(19) United States
(12) Patent Application Publication
(10) Pub. No.: US 2007/0132620 A1
(43) Pub. Date: Jun. 14, 2007

(54) ARRAY SUBSTRATE AND DISPLAY DEVICE

(75) Inventor: Takashi NAKAMURA, Saitama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Toshiba Matsushita Display Technology Co., Ltd., Tokyo (JP)

(21) Appl. No.: 11/566,028

(22) Filed: Dec. 1, 2006

(30) Foreign Application Priority Data
Dec. 14, 2005 (JP) 2005-360636

(51) Int. Cl. H03M 1/66

(52) U.S. Cl. 341/144

(57) ABSTRACT

An array substrate includes: a plurality of signal line groups, each of which is a set of a plurality of signal lines; a plurality of photoelectric conversion elements, each of which is connected to the signal lines on a pixel-to-pixel basis; a plurality of DA conversion circuits which are provided respectively corresponding to the signal line groups; a plurality of AD conversion circuits which are provided respectively corresponded to the signal line groups; and a selection circuit selecting any one of a connection of the DA conversion circuits to the respective signal line groups, and a connection of the AD conversion circuits to the respective signal line groups.

### CROSS REFERENCE OF THE RELATED APPLICATION

This application is based upon and claims the benefit of priority from the prior Japanese Patent Application No. 2005-360636, filed on Dec. 14, 2005; the entire contents of which are incorporated herein by reference.

### BACKGROUND OF THE INVENTION

1. Field of the Invention

The present invention relates to an array substrate having a photoelectric conversion element and to a display device provided with that array substrate.

2. Discussion of the Background

Recently, display devices such as a liquid crystal display have major advantages of thinness, lightweight and low power consumption, and are widely used as displays of a computer, a mobile phone and the like. Moreover, by adding an input function of input by use of a touch panel, a pen or the like to those display devices, a range of uses of the display devices have been expanded (refer to JP-A No. 2004-318819 (KOKAI) for example).

Such a display device is provided with a display unit, a signal line drive circuit, a sensor output circuit, and the like. The display unit has a plurality of sensor-integrated pixels respectively having built-in photo sensors, and a plurality of signal lines. The signal line drive circuit has a plurality of DA conversion circuits (digital-to-analog conversion circuits) to which video signals are inputted from an external circuit. The sensor output circuit has a plurality of AD conversion circuits (analog-to-digital conversion circuits) to which output signals are inputted from corresponding ones of the photo sensors.

The display unit, the signal line drive circuit and the sensor output circuit are provided on an array substrate. The display unit is provided in a vicinity of the center of the array substrate. The signal line drive circuit and the sensor output circuit are provided around the display unit, that is, in a frame region. In addition, each of the DA conversion circuits and each of the AD conversion circuits are provided corresponding to each of the signal lines.

Not only the display unit is used for displaying an image, but also the display unit has a read function for various purposes. This read function is carried out by detecting direct light from a light pen and reflected light of backlight light or the like from an object by use of the photo sensors in the sensor-integrated pixels.

However, the DA conversion circuits and the AD conversion circuits are provided respectively corresponding to the signal lines. This configuration needs a large number of each of the circuits, and thus needs the signal line drive circuit and the sensor output circuit made large. In order to provide these signal line drive circuit and sensor output circuit on the array substrate, it is necessary to enlarge the frame region on the array substrate. As a result, the array substrate becomes large.

### SUMMARY OF THE INVENTION

An object of the present invention is to provide a small array substrate and a display device.

According to a first aspect of the present invention, there is provided an array substrate which includes: a plurality of signal line groups, each of which is a set of a plurality of signal lines; a plurality of photoelectric conversion elements, each of which is connected to the plurality of signal lines on a pixel to pixel basis; a plurality of DA conversion circuits which are provided respectively corresponding to the plurality of signal line groups; a plurality of AD conversion circuits which are provided respectively corresponding to the plurality of signal line groups; and a selection circuit selecting any one of a connection of the plurality of DA conversion circuits respectively to the plurality of signal line groups and a connection of the plurality of AD conversion circuits respectively to the plurality of signal line groups.

In accordance with the first aspect of the present invention, by providing the selection circuit, it is unnecessary to provide the DA conversion circuit and the AD conversion circuit for each of the signal lines. As a result, the number of each of the circuits decreases. Thus it is possible to make the array substrate smaller.

According to a second aspect of the present invention, there is provided an array substrate which includes: a plurality of signal line groups, each of which is a set of a plurality of signal lines; a plurality of precharge lines which are provided respectively corresponding to the plurality of signal line groups; a plurality of output lines which are provided respectively corresponding to the plurality of signal line groups; a plurality of photoelectric conversion elements which are connected respectively to the plurality of precharge lines and respectively to the plurality of output lines on a pixel to pixel basis; a plurality of DA conversion circuits which are provided respectively corresponding to the plurality of signal line groups; a plurality of precharge circuits which are provided respectively corresponding to the plurality of signal line groups; a plurality of AD conversion circuits which are provided respectively corresponding to the plurality of signal line groups; and a selection circuit selecting any one of a connection of the plurality of DA circuits respectively to the plurality of signal line groups, a connection of the plurality of precharge circuits respectively to the plurality of signal line groups and respectively to the plurality of precharge lines, and a connection of the plurality of AD conversion circuits respectively to the plurality of output lines.

In accordance with the second aspect of the present invention, by providing the selection circuit, it becomes unnecessary to provide the DA conversion circuit, the AD conversion circuit, and the precharge circuit for each of the signal lines. As a result, the number of each of the circuits decreases. Thus, it is possible to make the array substrate smaller.

According to a third aspect of the present invention, there is provided a display device includes an array substrate corresponding to the above-described first or second aspect.

In accordance with the third aspect of the present invention, by providing the array substrate corresponding to the above-described first or second aspect, it is possible to make the display device smaller.

### BRIEF DESCRIPTION OF THE DRAWINGS

FIG. 1 is a block diagram showing a schematic configuration of a display device according to a first embodiment of the present invention;

FIG. 2 is a circuit diagram showing a schematic configuration of a sensor-integrated pixel included in the display device shown in FIG. 1;

FIG. 3 is a block diagram showing a schematic configuration of a control circuit included in the display device shown in FIG. 1;

FIG. 4 is a pattern diagram showing a schematic configuration of a signal line drive circuit included in the display device shown in FIG. 1;

FIG. 5 is a timing chart for describing an operation of the sensor-integrated pixel shown in FIG. 2;

FIG. 6 is a circuit diagram showing a schematic configuration of a sensor-integrated pixel included in a display unit according to a second embodiment of the present invention;

FIG. 7 is a pattern diagram showing a schematic configuration of a signal line drive circuit included in the display device according to the second embodiment of the present invention;

FIG. 8 is a timing chart for describing an operation of the sensor-integrated pixel shown in FIG. 6;

FIG. 9 is a circuit diagram showing a schematic configuration of a sensor-integrated pixel included in a display device according to a third embodiment of the present invention; and

FIG. 10 is a timing chart for describing an operation of the sensor-integrated pixel shown in FIG. 9.

### DETAILED DESCRIPTION OF THE INVENTION

### First Embodiment

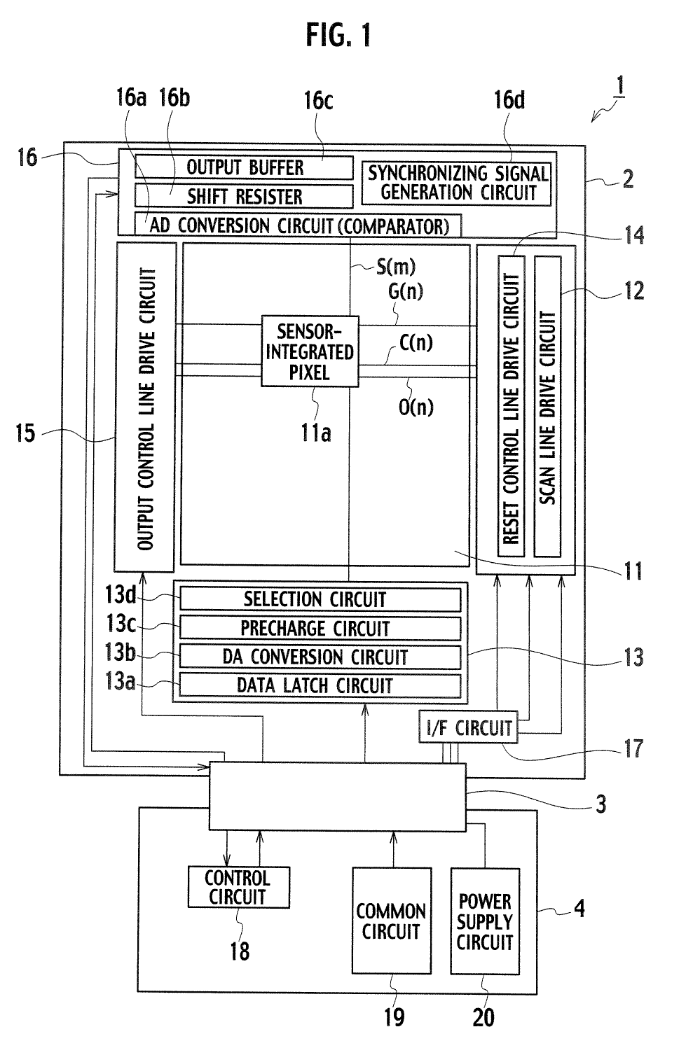

A first embodiment of the present invention will be described by referring to FIGS. 1 to 5.

As shown in FIG. 1, a display device 1 of the first embodiment is provided with an array substrate 2 and an external substrate 4. The array substrate 2 is formed of a translucent substrate such as a glass substrate. The external substrate 4 is connected to the array substrate 2 with a flexible substrate 3 in between. For example, a print substrate or the like is used as the external substrate.

The array substrate 2 is provided with: a display unit 11 displaying an image; a scan line drive circuit 12 outputting a scan signal GATE to scan lines G (n: a positive integer); a signal line drive circuit 13 outputting a video signal to signal lines S (m: a positive integer); a reset control line drive circuit 14 outputting a reset control signal CRT to reset control lines C (n); an output control line drive circuit 15 outputting an output control signal OPT to output control lines O (n); a sensor output circuit 16 outputting sensor output data to the external substrate 4; an I/F (interface) circuit 17 for the external substrate 4; and the like.

The external substrate 4 is provided with: a control circuit 18 outputting various kinds of signals including a control signal to the array substrate 2; a common circuit 19 supplying a common voltage to the array substrate 2; a power supply circuit 20 supplying various kinds of voltages to the array substrate 2; and the like. Note that, the flexible substrate 3 is provided with a plurality of wirings which electrically connects the array substrate 2 to the external substrate 4.

The display unit 11 is provided to be located in a substantial center on the array substrate 2. In addition, the scan line drive circuit 12, the signal line drive circuit 13, the reset control line drive circuit 14, the output control line drive circuit 15, the sensor output circuit 16, and the I/F (interface) circuit 17 are provided to be located in a region other than the display region where the display unit 11 is provided on the array substrate 2, that is, in a frame region.

To be more precise, the scan line drive circuit 12 and the reset control line drive circuit 14 are arranged to the right of the display unit 11. The signal line drive circuit 13 is arranged under the display unit 11. Moreover, the output control line drive circuit 15 is arranged to the left of the display unit 11, and the sensor output circuit 16 is arranged above the display unit 11. Note that, the scan line drive circuit 12, the signal line drive circuit 13, the reset control line drive circuit 14, the output control line drive circuit 15 and the sensor output circuit 16 are integrally formed on the array substrate 2.

The display unit 11 is provided with the plurality of scan lines G(n), the plurality of signal lines S(m), the plurality of reset control lines C(n), the plurality of output control lines O(n), a plurality of sensor-integrated pixels 11a, and the like. The scan lines G(n) and the signal lines S(m) are provided to cross one another. The reset control lines C(n) and the output control lines O(n) are provided in parallel with the scan lines G(n). The sensor-integrated pixels 11a are connected respectively to the scan lines G(n), respectively to the signal lines S(m), respectively to the reset control lines C(n), and respectively to the output control lines O(n). This display unit 11 has a display function to display an image corresponding video data and a read function (a light input function) to photograph an image of an external object such as a finger or a pen that comes close to the display screen.

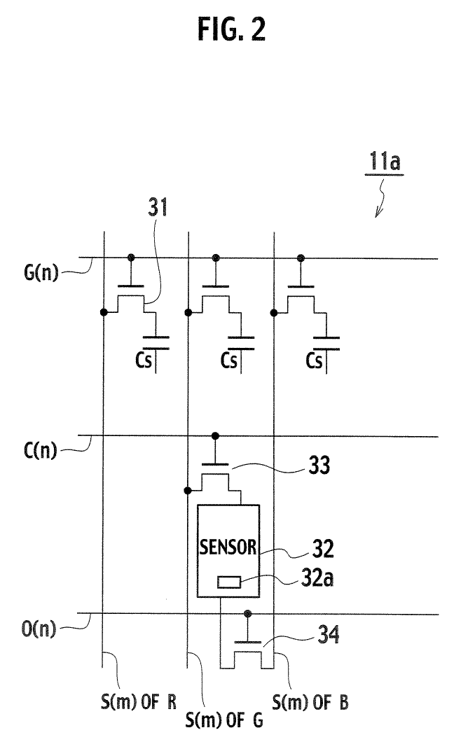

As shown in FIG. 2, each of the sensor-integrated pixels 11a is provided with three pixel transistors 31 and a photo sensor 32. Each of the pixel transistors 31 is arranged at the intersection between the scan line G(n) and each of the signal lines S(m). The photo sensor 32 is connected to the reset control line C(n) and the output control line O(n). This photo sensor 32 is configured of a photoelectric conversion element 32a converting light into an electric energy, a sensor capacitor, an amplifier circuit (for example, a source follower circuit), and the like. Note that, in the first embodiment, the number of the pixel transistors 31 is three, because one pixel is formed by three-color RGB dots.

The gate of each of the pixel transistors 31 is connected to the scan line G(n), the source thereof is connected to the signal line S(m), and the drain thereof is connected to a pixel capacitor and an auxiliary capacitor Cs. In addition, the photo sensor 32 is connected to the signal line S(m) with two control transistors 33 and 34 in between. The gate of the control transistor 33 is connected to the reset control line C(n), the source thereof is connected to the signal line S(m) of G, and the drain thereof is connected to the photo sensor 32. In addition, the gate of the control transistor 34 is connected to the output control lines O(n), the source thereof is connected to the photo sensor 32, and the drain thereof is connected to the signal line S(m) of B. Note that a GND (grand) of the photo sensor 32 is connected to the signal line S(m) of R or a GND line (not illustrated) by wiring (not illustrated).

Here, for example, a thin film transistor (TFT) or the like is used as the pixel transistor 31 and the control transistors 33 and 34. In addition, for example, a photodiode or the like is used as the photoelectric conversion element 32a included in the photo sensor 32.

The scan line drive circuit 12 is a circuit that sequentially outputs scan signals GATE to each of the scan lines G(n) at every horizontal period, that is, at every video writing period in one horizontal period, and that drives each of the scan lines G(n). Here, the scan signal GATE is a signal for driving (turning on) the pixel transistors 31.

The signal line drive circuit 13 is a circuit that outputs video signals to each of the signal lines S(m) in synchronization with corresponding one of the scan signals GATE, and drives each of the signal lines S(m). Here, the video signal is a signal for applying a voltage to each of the pixel capacities based on the video data.

The reset control line drive circuit 14 is provided with a shift resister and a buffer circuit. This reset control line drive circuit 14 outputs reset control signals CRT to each of the reset control lines C(n), by means of the buffer circuit, based on shift pulses sequentially propagating in the shift resister, and thus sequentially drives each of the reset control lines C(n). Here, the reset control signal CRT is a signal for driving (turning on) the control transistor 33.

The output control line drive circuit 15 is provided with a shift resister and a buffer circuit. This output control line drive circuit 15 outputs output control signals OPT to each of the output control lines O(n), by means of the buffer circuit, based on shift pulses sequentially propagating in the shift resister, and thus sequentially drives each of the output control lines O(n). Here, the output control signal O(n) is a signal for driving (turning on) the control transistor 34.

The sensor output circuit 16 is configured of an AD conversion circuit (an analog-to-digital conversion circuit) 16a, a shift resister 16b, an output buffer 16c, a synchronizing signal generation circuit 16d and the like. The AD conversion circuit 16a is provided with a comparator or the like. This AD conversion circuit 16a compares a potential of a sensor output signal from the photo sensor 32 with a reference potential, converts the sensor output signal to a digital signal, and outputs the digital signal obtained by the conversion to the shift resister 16b. In addition, the synchronizing signal generation circuit 16d generates a control clock, and outputs the control clock to the shift resister 16b.

The shift resister 16b stores the digital signal inputted from the AD conversion circuit 16a at each stage, and outputs the stored digital signal bit-by-bit as sensor output data in synchronization with the control clock inputted from the synchronizing signal generation circuit 16d. The output buffer 16c adjusts the amplitude of the output from the shift resister 16b depending on the interface of the control circuit 18, and carries out an amplifying operation for adjusting the amplitude to a drive load up to the external circuit such as the control circuit 18.

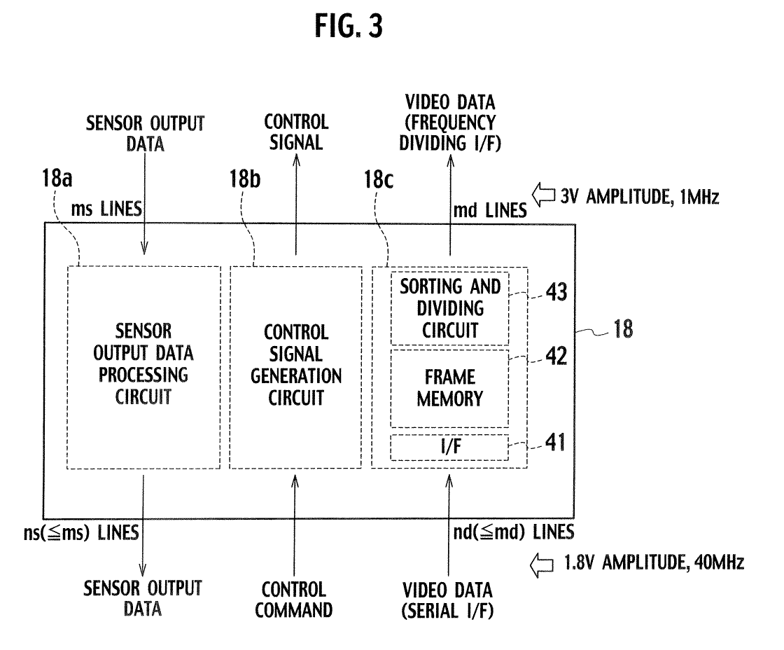

As shown in FIG. 3, the control circuit 18 is provided with a sensor output data processing circuit 18a, a control signal generation circuit 18b, a video data processing circuit 18c and the like. The sensor output data processing circuit 18a receives sensor output data transmitted from the sensor output circuit 16 of the array substrate 2, carries out a predetermined image process on the sensor output data, and transmits the data obtained after the image process to a host device. In addition, the control signal generation circuit 18b generates various kinds of control signals in response to the respective control commands transmitted from the host device, and transmits the various kinds of control signals, thus generated, to the array substrate 2.

The video data processing circuit 18c is configured of: a serial I/F 41 that is an interface to the host side; a frame memory 42 storing video data; a sorting and dividing circuit 43 sorting and dividing the video data stored in the frame memory 42; and the like. This video data processing circuit 18c receives digital video data transmitted from the host side, stores the video data in the frame memory 42, sorts and divides the stored video data, and transmits the sorted and divided video data to the signal line drive circuit 13 of the array substrate 2. Note that the digital video data is sorted depending on the circuit configuration of the signal line drive circuit 13 of the array substrate 2, and then is transmitted.

The control circuit 18 mentioned above has a high-speed logic circuit, a high-speed memory circuit and the like. Accordingly, it is more advantageous from viewpoints of costs and size to form the control circuit 18 consisting of an integrated LSI (integrated circuit) than to form the control circuit 18 consisting of individual LSIs. In addition, an I/F to the host device is the serial I/F 41 with low voltage and high frequency. On the other hand, an I/F to the array substrate 2 is a frequency dividing I/F with relatively high voltage and low frequency. The operation of a circuit formed on an insulator substrate such as the array substrate 2 is slower than the operation of a circuit formed on a silicon substrate such as the external substrate 4. Thus, it is advantageous to configure the external substrate 4 as described above.

Next, the signal line drive circuit 13 will be described in detail

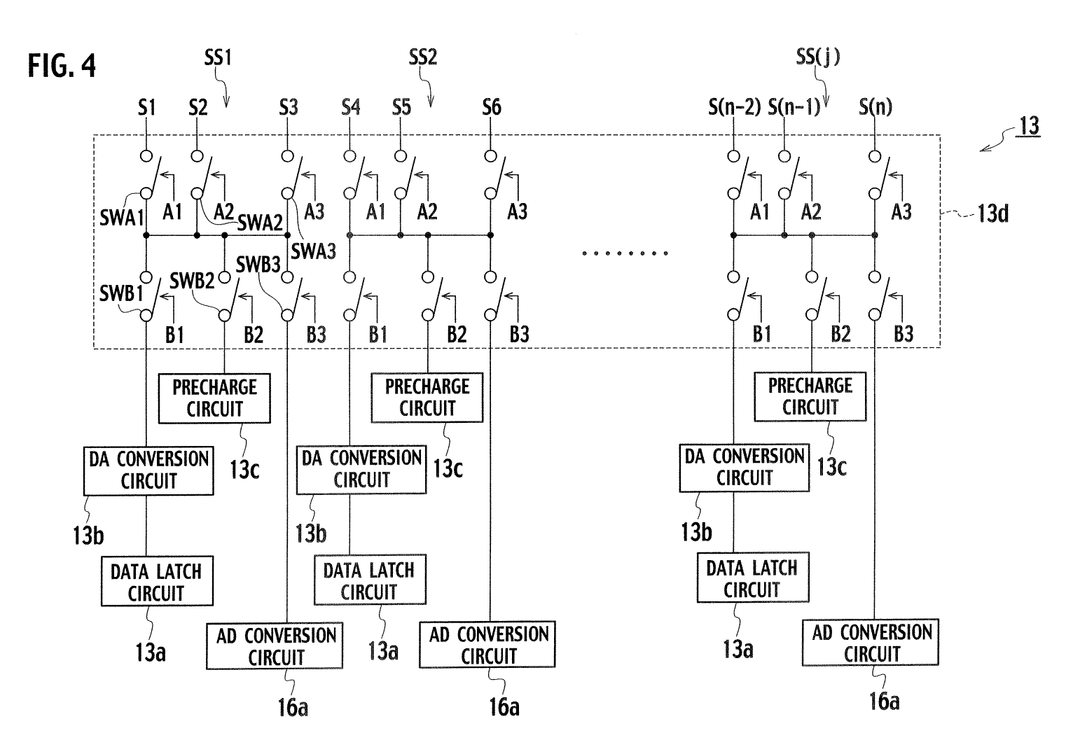

As shown in FIGS. 1 and 4, the signal line drive circuit 13 is configured of: data latch circuits 13a storing digital video data transmitted from the control circuit 18; DA conversion circuits (digital-to-analog conversion circuits) 13b that convert the digital video data stored in the data latch circuit 13a to an analog signal, and that output the analog signal obtained by the conversion as a video signal; precharge circuits 13c precharging each of the signal lines S(m) to a predetermined potential; a selection circuit 13d selectively connecting each of the signal lines S(m) to the output of the DA conversion circuit 13b, the output of the precharge circuit 13c or the like; and the like. Noted that, based on the precharge control signals PRCR, PRCG, and PRCB, which are transmitted from the control circuit 18, each of the precharge circuits 13c supplies a voltage supplied from the power supply circuit 20 to corresponding one of the signal lines S(m),

As shown in FIG. 4, the signal lines S(m) are divided into a plurality of signal line groups SS(j: a positive integer). In the first embodiment, the signal lines S(m) are divided into a plurality of signal line groups SS(j) each including, for example, three signal lines S(m). Thus, one signal line group SS(j) is a set of three signal lines S(m).

The plurality of data latch circuits 13a are provided on the array substrate 2 respectively corresponding to the signal line groups SS(j). In addition, the plurality of DA conversion circuits 13b are provided on the array substrate 2 respectively corresponding to the signal line groups SS(j). Furthermore, the plurality of precharge circuits 13c are also provided on the array substrate 2 respectively corresponding to the signal line groups SS(j). Here, the plurality of data latch circuits 13a are respectively connected to the DA conversion circuits 13b.

The selection circuit 13d is configured of a plurality of switching elements SWA1, a plurality of switching elements SWA2, and a plurality of switching elements SWA3, and a plurality of switching elements SWB1, a plurality of switching elements SWB2, and a plurality of switching elements SWB3. Three switching elements, that is, one of the switching elements SWA1, one of the switching elements SWA2, and one of the switching elements SWA3, are connected to each of the signal line groups SS(j). Three switching elements, that is, one of the switching elements SWB1, one of the switching elements SWB2, and one of the switching elements SWB3, are connected to each of the signal line groups SS(j), respectively to the three corresponding switching elements SWA1, SWA2 and SWA3.

Drive controls, that is, on-off controls (switching controls) of the switching elements SWA1, SWA2, and SWA3 are carried out by means of the respective switch control signals A1, A2, and A3, which are transmitted from the control circuit 18. In addition, drive controls, that is, on-off controls (switching controls) of the switching elements SWB1, SWB2, and SWB3 are also carried out by means of the respective switching control signals B1, B2, and B3, which are transmitted from the control circuit 18.

The selection circuit 13d selects any one of a connection of the DA conversion circuits 13b to the respective signal line groups SS(j), a connection of the AD conversion circuits 16a to the respective signal line groups SS(j), and a connection of the precharge circuits 13c to the respective signal line groups SS(j).

Here, in a case where the DA conversion circuits 13b are connected to the signal lines S1, S4, . . . , and S(n-2) of R, respectively, the switching control signal A1 and the switching control signal B1 are set to active states. In response to this, each of the switching elements SWA1 and each of the switching elements SWB1 become in the on-state. Thus, each of the signal lines S1, S4, . . . , and S(n-2) of R, and corresponding one of the DA conversion circuits 13b are connected to each other. With this, an output of each of the DA conversion circuits 13b is written into corresponding one of the signal lines S1, S4, . . . , and S(n-2). Similarly, in a case where the DA conversion circuits 13b are connected to the signal lines S2, S5, . . . , and S(n-1) of G, respectively, the switching control signal A2 and the switching control signal B1 are set to the active states. In addition, in a case where the DA conversion circuits 13b are connected to the signal lines S3, S6, . . . , and S(n) of B, respectively, the switching control signal A3 and the switching control signal B1 are set to the active states.

In a case where the precharge circuits 13c are connected to the signal lines S1, S4, . . . , and S(n-2), respectively, the switching control signal A1 and the switching control signal B2 are set to the active states. In response to this, each of the switching elements SWA1 and each of the switching elements SWB2 become in the on-state. Thus, each of the signal lines S1, S4, . . . , and S(n-2) of R, and corresponding one of the precharge circuits 13c are connected to each other. Thereby, a precharge voltage Vprc is written into the signal lines S1, 54, . . . , and S(n-2) of R. Similarly, in a case where the precharge circuits 13c are connected to the signal lines S2, S5, . . . , and S(n-1) of G, respectively, the switching control signal A2 and the switching control signal B2 are set to the active states. In addition, in a case where the precharge circuits 13c is connected to the signal lines S3, S6, . . . , and S(n) of B, respectively, the switching control signal A3 and the switching control signal B2 are set to the active states.

In order to connect the signal lines S3, S6, . . . , and S(n) of B to the AD conversion circuits 16a, respectively, the switching control signal A3 and the switching control signal B3 are set to the active states. In response to this, each of the switching elements SWA3 and each of the switching elements SWB3 become in the on-state. Thus, each of the signal lines S3, S6, . . . , and S(n) of B, and corresponding one of the AD conversion circuits 16a are connected to each other. With this, an output of each of the photo sensors 32 is inputted to corresponding one of the AD conversion circuits 16a in response to the driving of the control transistor 34 by the output control signal OPT.

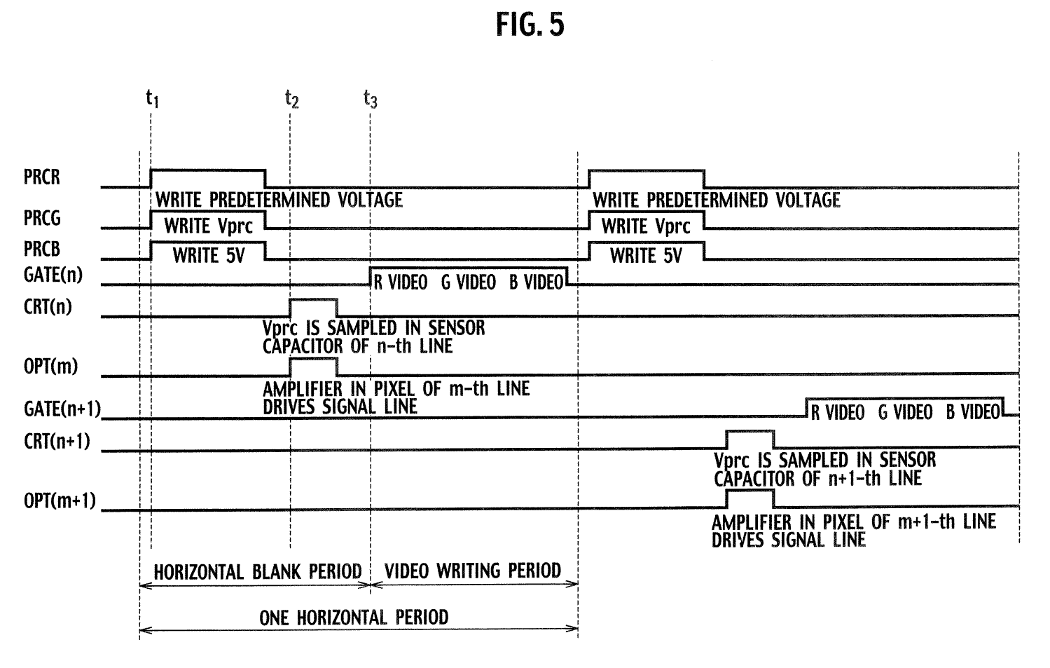

Next, a circuit operation of the sensor-integrated pixel 11a will be described by referring to the timing chart of FIG. 5.

FIG. 5 shows relationships between a scan signal GATE(n) and the pixel transistor 31, between a reset control signal CRT(n) and the photo sensor 32, between an output control signal OPT(m) and the photo sensor 32, and between the precharge circuit 13c and each of precharge control signals PRCR, PRCG, and PRCB. Here, one horizontal period is configured of a horizontal blank period and a video writing period.

When the control circuit 18 causes the precharge control signal PRCR to be at a high level at a time t1 in one horizontal period, the switching control signal A1 and the switching control signal B2 also become in the active state. As a result, each of the switching elements SWA1 and each of the switching elements SWB2 become in the on-state. With this, each of the signal lines S1, S4, . . . , and S(n-2) of R, and corresponding one of the precharge circuits 13c are connected to each other. Thus, a predetermined voltage is written into each of the signal lines S1, S4, . . . , and S(n-2) of R by corresponding of the precharge circuits 13c.

In addition, when the control circuit 18 causes the precharge control signal PRCG to be at a high level, the switching control signal A2 and the switching control signal B2 also become in the active state at predetermined timing. As a result, each of the switching elements SWA2 and each of the switching elements SWB2 become in the on-state. With this, each of the signal lines S2, S5, . . . , and S(n-1) of G and corresponding one of the precharge circuits 13c are connected to each other. Thus, the precharge voltage Vprc for sensor is written into each of the signal lines S2, S5, . . . , and S(n-1) of G by corresponding one of the precharge circuits 13c.

Furthermore, when the control circuit 18 causes the precharge control signal PRCB to be at a high level, the switching control signal A3 and the switching control signal B2 become in the active state at predetermined timing. As a result, each of the switching elements SWA3 and each of the switching elements SWB2 become in the on-state. With this, each of the signal lines S3, S6, . . . , and S(n) of B and corresponding one of the precharge circuits 13c are connected to each other. Thus, a predetermined voltage of 5V is written into each of the signal lines S3, S6, . . . , and S(n) by corresponding one of the precharge circuits 13c.

When the reset control line drive circuit 14 causes the reset control signal CRT(n) to be at a high level at a time t2 in one horizontal period, the control transistors 33 corresponding to the reset control line C(n) become in the on-state. Thus, the precharge voltage Vprc held in each of the signal lines S2, S5, . . . , and S(n-1) of G is precharged in the photo sensor 32, that is, the sensor capacitor, of each of the sensor-integrated pixels 11a corresponding to the reset control line C(n).

In addition, when the output control line drive circuit 15 causes the output control signal OPT(m) to be at a high level, the control transistors 34 corresponding to the output control line O(m) become in the on-state. Thus, the photo sensor 32, that is, an output terminal of the amplifier circuit, of each of the sensor-integrated pixels 11a corresponding to the scan line G(m) is electrically connected to the signal line S(m). At this time, in a case where a potential of the sensor capacitor is high, a potential outputted to the signal line S(m) largely decreases from 5 V. On the other hand, in a case where the potential of the sensor capacitor is low, the potential outputted to the signal line S(m) does not substantially change from 5V. In this manner, the sensor output signal from the photo sensor 32 is outputted.

When the scan line drive circuit 12 causes the scan signal GATE(n) to be at a high level at a time t3 in one horizontal period, writing of video signals R, G, and B into each of the signal lines S(m) is started by the signal line drive circuit 13. At this time, the switching control signal A1 and the switching control signal B1 become in the active state, and each of the switching elements SWA1 and each of the switching elements SWB1 become in the on-state. With this, each of the signal lines S1, S4, . . . , and S(n-2) of R and corresponding one of the DA conversion circuits 13b are connected to each other. An output of each of the DA conversion circuits 13b is written into corresponding one of the signal lines S1, S4, . . . , and S(n-1) of R. Similarly, an output of each of the DA conversion circuits 13b are also written into corresponding one the signal lines S2, S5, . . . , and S(n-1) of G and each of the signal lines S3, S6, . . . , and S(n) of B. Upon completion of the writing of the video signals, the one horizontal period ends. Here, one horizontal period is, for example, 50 μs.

In this manner, the precharge and the output processing of the photo sensor 32 and the writing of the video signal into the signal line S(m) are sequentially carried out in this order. In other words, within a period other than the period of writing the video in one horizontal period, that is, within a horizontal blank period, the precharge and the output processing of the photo sensor 32 are carried out by using each of the signal lines S(m).

As described above, according to the first embodiment, by providing the selection circuit 13d on the array substrate 2, it becomes unnecessary to provide the DA conversion circuit 13b and the AD conversion circuit 16a for each of the signal lines S(m). This results in a decrease in the numbers respectively of the DA conversion circuit 13b and the AD conversion circuit 16a decrease, and thus can make the signal line drive circuit 13 and the sensor output circuit 16 smaller. Thereby, the array substrate 2 can be made smaller, and power consumption can be also reduced.

Furthermore, it also becomes unnecessary to provide the precharge circuit 13c for each of the signal lines S(m). This also results in a decease in the number of the precharge circuits 13c, and thus can make the signal line drive circuit 13 smaller. Thereby, the array substrate 2 can be even smaller.

In addition, by providing the external substrate 4 having the control circuit 18 outputting various kinds of control signals to the array substrate 2, it can be prevented that various kinds of circuits are all integrated on the array substrate 2, and that the array substrate 2 becomes larger.

In addition, it can be prevented that various kinds of circuits are all integrated on the array substrate 2 by providing the sensor output data processing circuit 18a and the sorting and dividing circuit 43 in the control circuit 18, the sensor output data processing circuit 18a processing sensor output data obtained by a plurality of photo sensors 32, and the sorting dividing circuit 42 sorting and dividing video data. Moreover, by providing the sort and clock division circuit 43, it becomes possible to perform an operation following the high-speed I/F (interface) on the host side. This makes it possible to avoid deterioration of image quality, which would otherwise be caused due to the incapability of performing the following operation.

### Second Embodiment

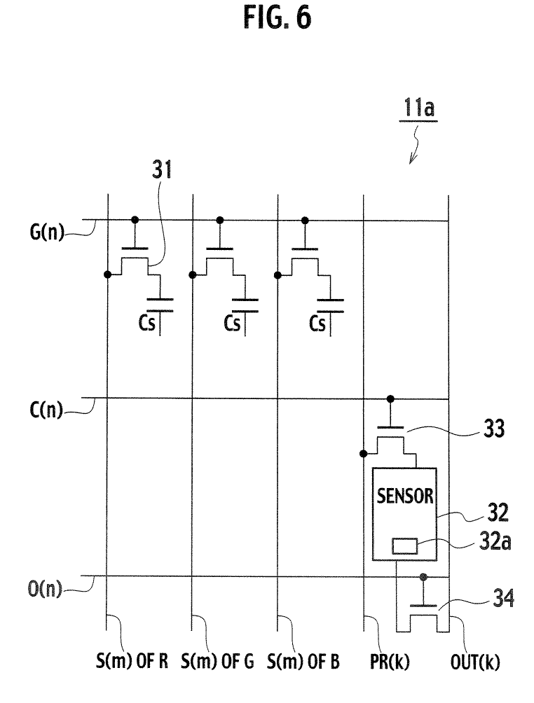

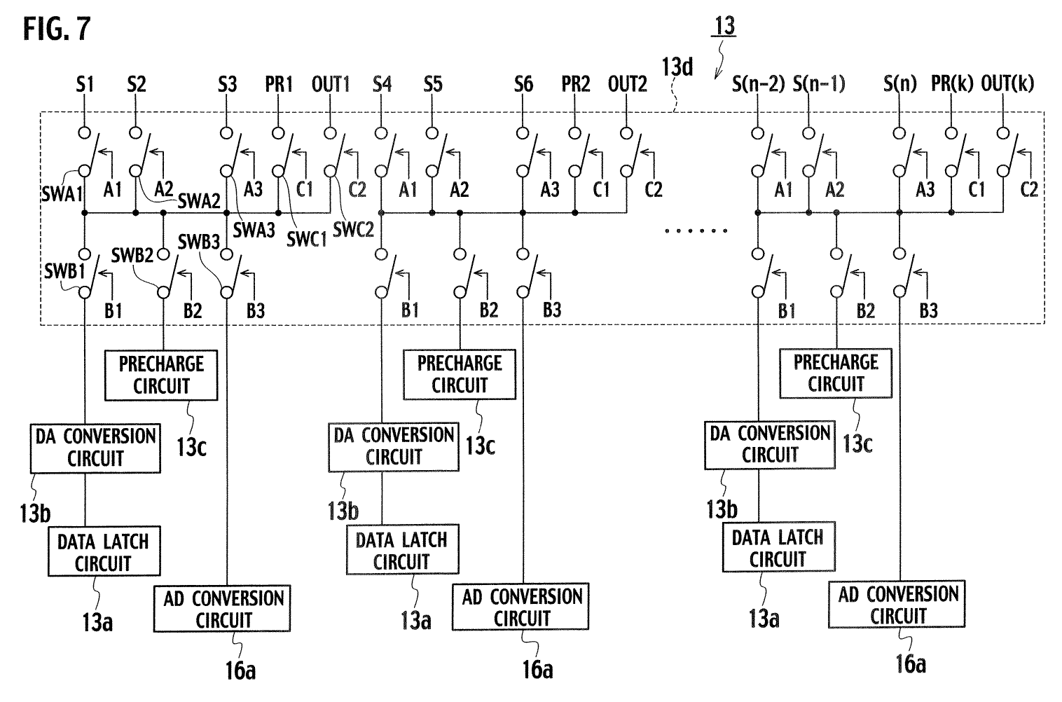

A second embodiment of the present invention will be descried by referring to FIGS. 6 to 8.

A configuration of a second embodiment is basically similar to that of the first embodiment. The points different from the first embodiment will be mainly described below, and the already-described points will be omitted.

As shown in FIG. 6, a plurality of precharge lines PR(k) are provided respectively corresponding to the photo sensors 32. Each of the precharge lines PR(k) supplies a precharge voltage Vprc to corresponding one of the photo sensors 32. In addition, a plurality of output lines OUT(k) are provided respectively corresponding to the photo sensors 32. The output lines OUT(k) are respectively used for outputting sensor output signals of the photo sensors 32 to the AD conversion circuits 16a.

A gate of a control transistor 33 is connected to a reset control line C(n), a source thereof is connected to the precharge line PR(k: a positive integer), and a drain thereof is connected to the photo sensor 32. In addition, a gate of a control transistor 34 is connected to an output control line O(n), a source thereof is connected to the photo sensor 32, and a drain thereof is connected to the output line OUT(k). Note that a GND (ground) of the photo sensor 32 is connected to a GND line (not illustrated) arranged in a column direction or a line direction.

A selection circuit 13d is configured of a plurality of switching elements SWC1 and a plurality of switching elements SWC2 in addition to a plurality of switching elements SWA1, SWA2, and SWA3 and a plurality of switching elements SWB1, SWB2, and SWB3. Three of switching elements SWA1, SWA2, and SWA3 are respectively connected to three signal lines S(m) in each of the signal line groups SS(j). Three of switching elements SWB1, SWB2, and SWB3 are respectively connected to three single lines in each of the signal line groups SS(j), corresponding to respective three switching elements SWA1, SWA2, and SWA3. The plurality of switching elements SWC1 are connected to the respective precharge lines PR(k). The plurality of switching elements SWC2 are connected to the respective output lines OUT(k).

A drive control, that is, an on-off control (a switching control) of each of the switching elements SWC1 is carried out by means of a switching control signal C1 transmitted from the control circuit 18. In addition, a drive control, that is, anon-off control (a switching control) of each of the switching elements SWC2 is carried out by means of a switching control signal C2 transmitted from the control circuit 18.

This selection circuit 13d selects any one of a connection of the DA conversion circuits 13b to the respective signal line groups SS(j), a connection of the precharge circuits 13c to the respective signal line groups SS(j) and the respective precharge lines PR(k), and a connection of the AD conversion circuits 16a to the respective output lines OUT(k).

Here, in a case where the precharge circuits 13c are connected to the precharge lines PR1, PR2, . . . , and PR(k), respectively, the switching control signal C1 and the switching control signal B2 are set to the active states. In response to this, each of the switching elements SWC1 and each of the switching elements SWB2 become in the on-state. Thus, each of the precharge lines PR1, PR2, . . . , and PR(k), and corresponding one of the precharge circuits 13c are connected to each other. With this, a precharge voltage Vprc is written into each of the precharge lines PR1, PR2, . . . , and PR(k).

In order to respectively connect the AD conversion circuits 16a to the output lines OUT1, OUT2, . . . , and OUT(k), the switching control signal C2 and the switching control signal B3 are set to the active states. In response to this, each of the switching elements SWC2 and each of the switching element SWB3 become in the on-state. Thus, each of the output lines OUT1, OUT2, . . . , and OUT(k) and corresponding one of the AD conversion circuits 16a are connected to each other. With this, an output of each of the photo sensors 32 is inputted into corresponding one of the AD conversion circuits 16a in response to the driving of the control transistor 34 by the output control signal OPT.

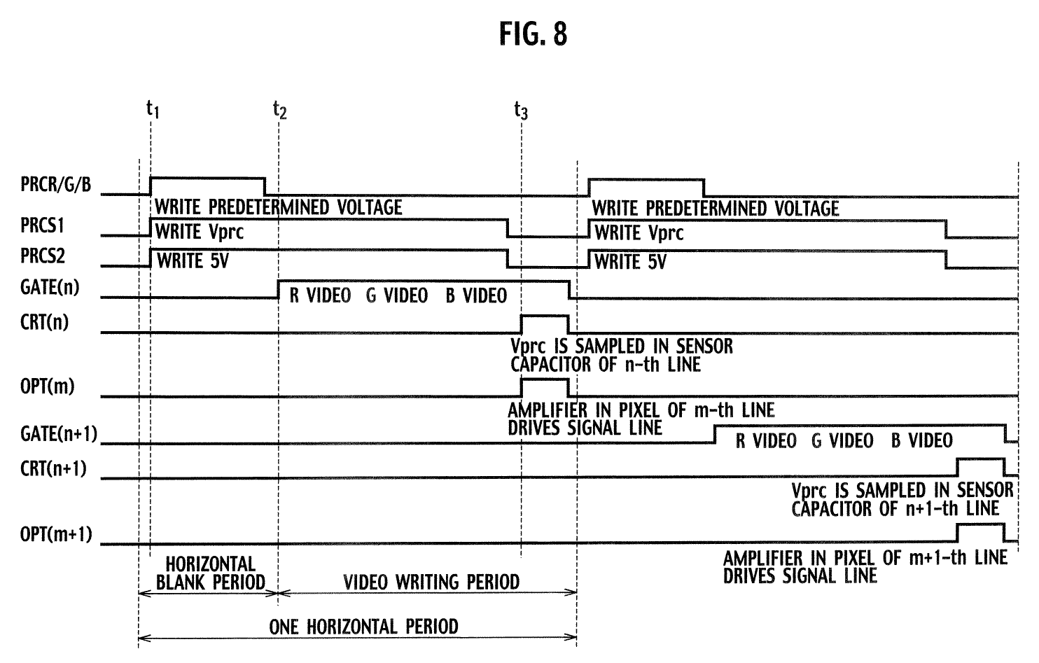

Next, a circuit operation of the sensor-integrated pixel 11a will be described by referring to the timing chart of FIG. 8.

FIG. 8 shows relationships between the scan signal GATE(n) and the pixel transistor 31, between the reset control signal CRT(n) and the photo sensor 32, between the output control signal OPT(m) and the photo sensor 32, and between the precharge circuit 13c and each of the precharge control signals PRCR, PRCG, and PRCB, and further between the control signal PRCS1 for the precharge line PR(k) of the precharge circuit 13c and the control signal PRCS2 for the output line OUT(k). Here, one horizontal period is configured of a horizontal blank period and a video writing period.

When the control circuit 18 causes the control signal PRCS1 to be at a high level by at a time t1 in one horizontal period, the switching control signal C1 and the switching control signal B2 become in the active state, and each of the switching elements SWC1 and each of the switching elements SWB2 become in the on-state. With this, each of the precharge lines PR1, PR2, . . . , and PR(k) and corresponding one of the precharge circuits 13c are connected to each other, and a precharge voltage Vprc is written into each of the precharge lines PR1, PR2, . . . , and PR(k) from corresponding one of the precharge circuits 13c.

In addition, when the control circuit 18 causes the control signal PRCS2 to be at a high level, the switching control signal C2 and the switching control signal B2 become in the active state at a predetermined timing. Thus, each of the switching elements SWC2 and each of the switching elements SWB2 become in the on-state. With this, each of the output lines OUT1, OUT2, . . . , and OUT(k) and corresponding one of the precharge circuits 13c are connected to each other. Then, a predetermined voltage of 5V is written into each of the output lines OUT1, OUT2, . . . , and OUT(k) from corresponding one of the precharge circuits 13c. On the other hand, when the precharge control signals PRCR, PRCG, and PRCB become at a high level, a predetermined voltage is written into each of the signal lines S(m) from corresponding one of the precharge circuits 13c.

When the scan line drive circuit 12 causes the scan signal GATE(n) to be at a high level at a time t2 in one horizontal period, writing of video signals R, G and B into each of the signal lines S(m) is started by the signal line drive circuit 13. At this time, the switching control signal A1 and the switching control signal B1 become in the active state. Thus, each of the switching elements SWA1 and each of the switching elements SWB1 become in the on-state. With this, each of the signal lines S1, S4, . . . , and S(n-2) of R and corresponding one of the DA conversion circuits 13b are connected to each other. Then, an output of each of the DA conversion circuits 13b is written into corresponding one of the signal lines S1, S4, and S(n-2) of R. Similarly, an output of each of the DA conversion circuits 13b is also written into corresponding one of the signal lines S2, S5, S8, . . . , and S(n-1) of G and corresponding one of the signal lines S3, S6, S9, . . . , and S(n) of B. Upon completion of writing of the video signals, the one horizontal period ends. Here, one horizontal period becomes, for example, 50 μs.

When the reset control line drive circuit 14 causes the reset control signal CRT(n) to be at a high level at a time t3 in one horizontal period, each of the control transistors 33 corresponding to the reset control line C(n) becomes at the on-state, and the precharge voltage Vprc held in the precharge line PR(k) is precharged in the photo sensor 32, that is, the sensor capacitor, of the sensor-integrated pixel 11a.

Furthermore, when the output control line drive circuit 15 causes the output control signal OPT(m) to be at a high level, the control transistors 34 corresponding to the output control line O(m) become in the on-state. Then, the photo sensor 32, that is, an output terminal of an amplifier circuit, of each of the sensor-integrated pixels 11a corresponding to the scan line G(m) is electrically connected to the output line OUT(k). At this time, in a case where a potential of the sensor capacitor is high, the potential outputted to the output line OUT(k) largely decreases from 5V. On the other hand, in a case where the potential of the sensor capacitor is low, the potential outputted to the output line OUT(k) does not substantially change from 5 V. In this manner, the sensor output signal of the photo sensor 32 is outputted.

These precharge processing and the output processing of the photo sensor 32 at the time t3 are carried out in parallel with the writing processing of the video signals R, G, and B to the respective signal lines S(m). Here, for example, it is assumed that m=n+1 is satisfied, and that a signal outputted from the photo sensor 32 by means of the output control signal OPT(m) is a signal having been precharged in the sensor capacitor for the horizontal period of the previous frame. Thereby, one frame period after the photo sensor 32 is precharged can be allocated to a period for detecting light from the outside, under the environment where outside light is dark.

In this manner, in parallel with the writing processing of the video signals into each of the signal lines S(m), the precharge processing and output processing of the photo sensor 32, and then the writing of the video signals are sequentially carried out. That is, within a period of writing the video in one horizontal period, the precharge processing and output processing of the photo sensor 32 are carried out by using each of the precharge lines PR(k) and each of the output lines OUT(k) This makes it unnecessary to carry out the precharge processing and output processing of the photo sensor 32 during the horizontal blank period, and thus makes it possible to shorten the horizontal blank period.

As described above, according to the second embodiment, the effects similar to those of the first embodiment can be obtained. Furthermore, during the period of writing the video signals, the precharge circuit 13c supplies a precharge voltage Vprc to the precharge line PR(k), and simultaneously supplies the predetermined voltage of 5V to the output line OUT(k). This makes it possible to carry out both the precharge processing of the photo sensor 32 through the precharge line PR(k) and the output processing of the photo sensor 32 through the output line OUT(k) in parallel with the writing processing of the video signals R, G, and B in the respective pixels through the corresponding signal lines S(m). Accordingly, as compared with the first embodiment, it becomes unnecessary to carry out the precharge and the output processing of the photo sensor 32 during the horizontal blank period. This makes it possible to reduce the horizontal blank period, while the operations of the precharge of the photo sensor 32 and the signal output from the photo sensor 32 are being performed.

### Third Embodiment

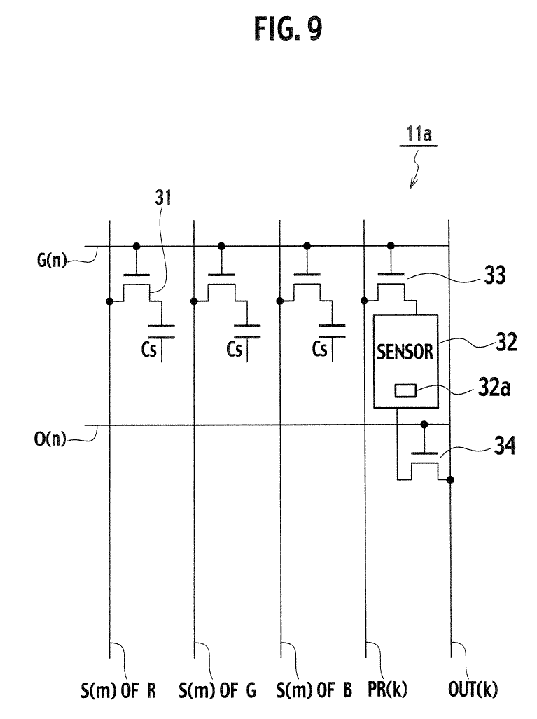

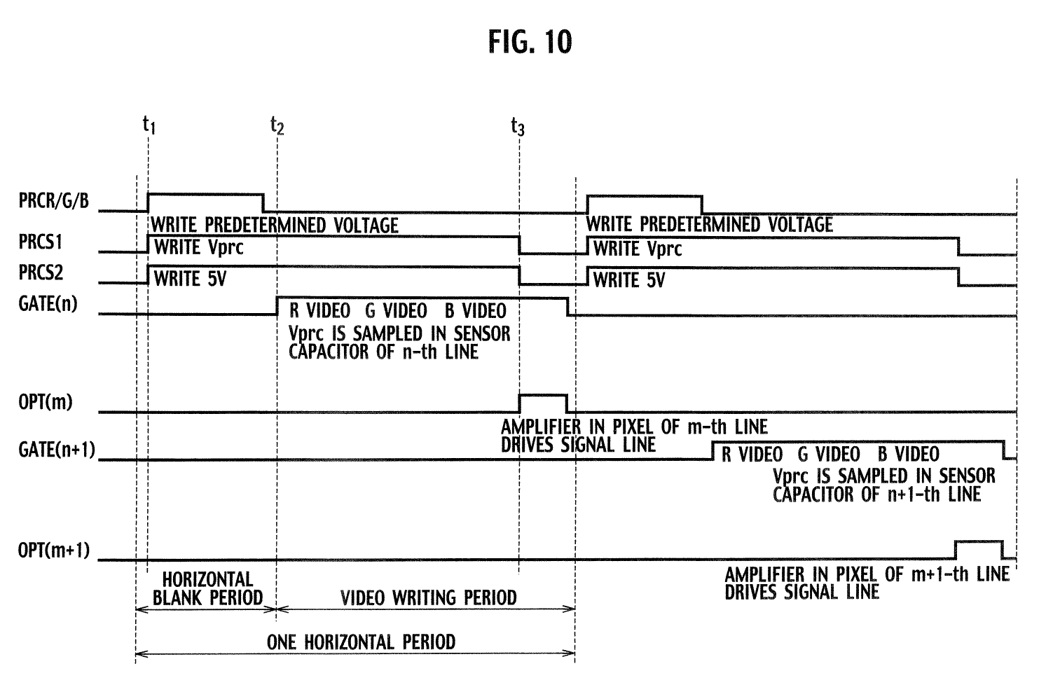

A third embodiment of the present invention will be described by referring to FIGS. 9 and 10.

A configuration of a third embodiment is basically similar to that of the second embodiment. The points different from the second embodiment will be mainly described below and the above-described points will be omitted.

As shown in FIG. 9, a gate of a control transistor 33 is connected to a scan line G(n), and the scan line G(n) is also used as a reset control line C(n). With this configuration, wirings for a sensor-integrated pixel 11a can be reduced by one. Note that a GND (ground) of a photo sensor 32 is connected to a GND line (not illustrated) arranged in a column direction or a line direction.

Next, a circuit operation of the sensor-integrated pixel 11a will be described by referring to a timing chart of FIG. 10.

FIG. 10 shows relationship between a scan signal GATE(n) and a pixel transistor 31, between an output control signal OPT(m) and the photo sensor 32, between a precharge circuit 13c and each of precharge control signals PRCR, PRCG and PRCB, between a precharge circuit 13c and each of a control signal PRCS1 for the precharge line PR(k) and a control signal PRCS2 for output line OUT(k). Here, one horizontal period is configured of a horizontal blank period and a video writing period.

When a control circuit 18 causes the control signal PRCS1 to be at a high level at a time t1 in one horizontal period, a switching control signal C1 and a switching control signal B2 become in the active state. Thus, each of switching elements SWC1 and each of switching elements SWB2 become in the on-state. Thereby, each of the precharge lines PR1, PR2, . . . , and PR(k) and corresponding one of the precharge circuits 13c are connected to each other, and a precharge voltage Vprc is written into each of the precharge lines PR1, PR2, . . . , and PR(k) from corresponding one of the precharge circuits 13c.

In addition, when the control circuit 18 causes the control signal PRCS2 to be at a high level, a switching control signal C2 and a switching control signal B2 become in the active state at a predetermined timing. Thus, each of switching elements SWC2 and each of switching elements SWB2 become in the on-state. Thereby, each of the output lines OUT1, OUT2, and OUT(k) and corresponding one of the precharge circuits 13c are connected to each other, and a predetermined voltage of 5 V is written into each of the output lines OUT1, OUT2, and OUT(k) from corresponding one of the precharge circuits 13c. On the other hand, when the precharge control signals PRCR, PRCG, and PRCB become at a high level, a predetermined voltage is written into each of the signal lines S(m) from corresponding one of the precharge circuit 13c.

When a scan line drive circuit 12 causes the scan signal GATE(n) to be at a high level at a time t2 in one horizontal period, writing of video signals R, G, and B to each of the signal lines S(m) is started by a signal line drive circuit 13. At the same time, a precharge voltage Vprc held in the precharge line PR(k) is precharged in the photo sensor 32 by a control transistor 33. At this time, a switching control signal A1 and a switching control signal B2 become in the active state, and each of switching elements SWA1 and each of switching elements SWB1 become in the on-state. Thereby, each of the signal lines S1, S4, . . . , and S(n-2) of R and corresponding one of DA conversion circuits 13b are connected to each other, and an output of each of the DA conversion circuits 13b is written into corresponding one of the signal lines S1, S4, . . . , and S(n-2) of R. Similarly, the output of each of the DA conversion circuits 13b is also written into corresponding one of the signal lines S2, S5, . . . , and S(n-1) of G and the signal lines S3, S6, . . . , and S(n) of B.

When an output control line drive circuit 15 causes the output control signal OPT(m) to be at a high level at a time t3 if one horizontal period, a control transistors 34 corresponding to the output control line O(m) become in the on-state. Thus, the photo sensor 32, that is, an output terminal of an amplifier circuit, of each of the sensor-integrated pixels 11a corresponding to the scan line G(m) is electrically connected to corresponding one of the output lines OUT(k). Here, the writing processing of the video signals R, G, and B to the respective signal lines S(m) is continuously carried out from the time t2. On completion of writing the video signals R, G, and B, one horizontal period ends.

In this manner, in parallel with the writing processing of the video signals into the respective signal lines S(m), the precharge and the output processing of the photo sensor 32, and then the writing of the video signals are sequentially carried out. That is, within a period of writing the video signals in one horizontal period, the precharge and the output processing of the photo sensors 32 are carried out by using the respective precharge lines PR(k) and the respective output lines OUT(k). This makes it unnecessary to carry out the precharge and the output processing of the photo sensor 32 during a horizontal blank period, and thus makes it possible to reduce the horizontal blank period.

As described above, according to the third embodiment of the present invention, effects similar to those of the second embodiment can be obtained. In addition, since the control transistors 33 for precharge are driven by the scan signal GATE, which would otherwise be transmitted only to the pixel transistors 31, the reset control line C(k), which is needed in the second embodiment, becomes unnecessary, and thus an aperture ratio of a pixel can be increased. Furthermore, although the second embodiment needs the reset control line drive circuit 14 on the array substrate 2, the third embodiment does not need it. This makes it possible to narrow the frame region.

### Other Embodiment

Note that the present invention is not limited to the above-described embodiments, but various modifications are possible without departing from the spirit or essential characteristics thereof.

For example, in the above-described embodiments, three pixel transistors 31 are provided in the sensor-integrated pixel 11a. However, the present invention is not limited to this number, and the number of pixel transistors is not limited. For example, four pixel transistors 31 may be provided in the sensor-integrated pixel 11a, and moreover, five pixel transistors 31 may be also provided in the sensor-integrated pixel 11a.

In addition, in the above-described embodiments, the signal lines S(m) are divided into a plurality of signal line groups SS(j) each including three signal lines S(m). However, the present invention is not limited to this, and the number is not limited. For instance, the signal lines S(m) may be divided into a plurality of signal line groups SS(j) each including four signal lines S(m). Moreover, the signal lines S(m) may also be divided into a plurality of signal line groups SS(j) each including five signal lines S(m).

In addition, in the above-described embodiments, the control circuit 18 is provided on the external substrate 4, but the present invention is not limited to this. For example, the control circuit 18 may be integrally formed on the array substrate 2 by using a low-temperature polysilicon technique. Alternatively, a semiconductor chip constituting the control circuit 18 may be directly mounted on the array substrate 2 (COG mount: chip on glass mount). In this case, a drive load on the control circuit 18 becomes smaller, and wiring load also becomes smaller. Accordingly, power consumption can be suppressed. In addition, the common circuit 19 and the power supply circuit 20 may be formed as one chip IC (integrate circuit). Furthermore, the IC may be directly mounted (COG mount) or transferred on the array substrate 2.

In addition, in the above-described embodiments, both of the precharge line PR(k) and the output line OUT(k) for the photo sensor 32 are provided independently from the signal line S(m). However, the present invention is not limited to this. For example, only the precharge line PR(k) may be provided independently from the signal line S(m). In this case, an amplifier circuit capable of performing a high-speed output operation is used as the amplifier circuit that writes the output signal from the photo sensor 32 into the signal line S(m). This makes it possible to reduce the horizontal blank period even in a case where the output from the photo sensor 32 is carried out by using the signal line S(m).

In addition, in the above-described embodiments, the scan line G(n) is also used only as the reset control line C(n), but the present invention is not limited to this. For example, the scan line G(n) may be also used only as the output control line O(n). In this case, in addition to the effects of the second embodiment, an aperture ration of pixel can be improved. This is because the control transistors 34 for output are driven by using the scan signal GATE, which would otherwise be transmitted to only the pixel transistors 31, and this configuration does not need the output control line O(n) that is needed in the second embodiment. In addition, although the second embodiment needs the output control line drive circuit 15 on the array substrate 2, this configuration does not need it. This makes it possible to narrow the frame region.

What is claimed is:

1. An array substrate comprising:
a plurality of signal line groups, each of which is a set of a plurality of signal lines;
a plurality of photoelectric conversion elements, each of which is connected to the plurality of signal lines on a pixel-to-pixel basis;
a plurality of DA conversion circuits which are provided respectively corresponding to the plurality of signal line groups;
a plurality of AD conversion circuits which are provided respectively corresponding to the plurality of the signal line groups; and
a selection circuit selecting any one of a connection of the plurality of DA conversion circuits respectively to the plurality of signal line groups, and a connection of the plurality of AD conversion circuits respectively to the plurality of signal line groups.

2. The array substrate according to claim 1, further comprising a plurality of precharge circuits which are provided respectively corresponding to the plurality of signal line groups,
wherein the selection circuit selects any one of a connection of the plurality of DA conversion circuits respectively to the plurality of signal line groups, a connection of the plurality of AD conversion circuits respectively to the plurality of signal line groups, and a connection of the plurality of precharge circuits respectively to the plurality of signal line groups.

3. An array substrate comprising:
a plurality of signal line groups, each of which is a set of a plurality of signal lines;
a plurality of precharge lines which are provided respectively corresponding to the plurality of signal line groups;
a plurality of output lines which are provided respectively corresponding to the plurality of signal line groups;
a plurality of photoelectric conversion circuits which are connected respectively to the plurality of precharge lines and respectively to the plurality of output lines, on a pixel-to-pixel basis;
a plurality of DA conversion circuits which are provided respectively corresponding to the plurality of signal line groups;
a plurality of precharge circuits which are provided respectively corresponding to the plurality of signal line groups;
a plurality of AD conversion circuits which are provided respectively corresponding to the plurality of signal line groups; and
a selection circuit selecting any one of a connection of the plurality of DA conversion circuits respectively to the plurality of signal line groups, a connection of the plurality of precharge circuits respectively to the plurality of signal line groups and respectively to the plurality of precharge lines, and a connection of the plurality of AD conversion circuits respectively to the plurality of output lines.

4. A display device comprising an array substrate, wherein the array substrate includes:
a plurality of signal line groups, each of which is a set of a plurality of signal lines;
a plurality of photoelectric conversion elements, each of which is connected to the plurality of signal lines on a pixel-to-pixel basis;
a plurality of DA conversion circuits which are provided respectively corresponding to the plurality of signal line groups;
a plurality of AD conversion circuits which are provided respectively corresponding to the plurality of the signal line groups; and
a selection circuit selecting any one of a connection of the plurality of DA conversion circuits respectively to the plurality of signal line groups, and a connection of the plurality of AD conversion circuits respectively to the plurality of signal line groups.

5. The display device according to claim 4,wherein the array substrate further includes a plurality of precharge circuits which are provided respectively corresponding to the plurality of signal line groups,
wherein the selection circuit selects any one of a connection of the plurality of DA conversion circuits respectively to the plurality of signal line groups, a connection of the plurality of AD conversion circuits respectively to the plurality of signal line groups, and a connection of the plurality of precharge circuits respectively to the plurality of signal line groups.

6. The display device according to claim 4, further comprising an external substrate having a control circuit which outputs a control signal to the array substrate.

7. The display device according to claim 5, further comprising an external substrate having a control circuit which outputs a control signal to the array substrate.

8. The display device according to claim 6, wherein the control circuit includes a processing circuit which processes output data obtained by the plurality of photoelectric conversion elements and a sorting and dividing circuit which sorts and divides video data.

9. The display device according to claim 7, wherein the control circuit includes a processing circuit which processes output data obtained by the plurality of photoelectric conversion elements and a sorting and dividing circuit which sorts and divides video data.

10. A display device comprising an array substrate, wherein the array substrate includes:
a plurality of signal line groups, each of which is a set of a plurality of signal lines;
a plurality of precharge lines which are provided respectively corresponding to the plurality of signal line groups;
a plurality of output lines which are provided respectively corresponding to the plurality of signal line groups;
a plurality of photoelectric conversion circuits which are connected respectively to the plurality of precharge lines and respectively to the plurality of output lines, on a pixel-to-pixel basis;
a plurality of DA conversion circuits which are provided respectively corresponding to the plurality of signal line groups;
a plurality of precharge circuits which are provided respectively corresponding to the plurality of signal line groups;
a plurality of AD conversion circuits which are provided respectively corresponding to the plurality of signal line groups; and
a selection circuit selecting any one of a connection of the plurality of DA conversion circuits respectively to the plurality of signal line groups, a connection of the plurality of precharge circuits respectively to the plurality of signal line groups and respectively to the plurality of precharge lines, and a connection of the plurality of AD conversion circuits respectively to the plurality of output lines.

11. The display device according to claim 10, further comprising an external substrate having a control circuit which outputs a control signal to the array substrate.

12. The display device according to claim 11, wherein the control circuit includes a processing circuit which processes output data obtained by the plurality of photoelectric conversion elements and a sorting and dividing circuit which sorts and divides video data.
